(19) United States
(12) Patent Application Publication
(10) Pub. No.: US 2010/0089450 A1
(43) Pub. Date: Apr. 15, 2010

(54) NEAR-FIELD DIFFRACTION SUPERPOSITION OF LIGHT BEAMS FOR CONCENTRATING SOLAR SYSTEMS

(76) Inventors: Jun Yang, Cupertino, CA (US); Xin Zhu, Fremont, CA (US)

Correspondence Address: Jun Yang, 10149 South Blaney Ave, Apt. D, Cupertino, CA, 95014, US

(21) Appl. No.: 12/579,422

(22) Filed: Oct. 15, 2009

Related U.S. Application Data
(60) Provisional application No. 61/196,260, filed on Oct. 15, 2008.

(51) Int. Cl. H01L 31/00

(52) U.S. Cl. 136/259

(57) ABSTRACT

Disclosed herein is a concentrating photovoltaic system utilizing a lens/reflector array to spatially divide the incident sunlight into separate incoherent beams, and a principle optical element to superpose the separate beams that undergo near-field diffraction/transmission, and form a uniform illumination pattern on the photovoltaic (PV) cell with similar shape and size. The array and principle optical element can be flexibly disposed in the system as long as the near-field diffraction condition is satisfied. The PV cell is disposed close to the focus of the principle optical element, and the concentrated illumination pattern on the PV cell is nearly a geometric projection of individual lens/reflector in the array. The size of the pattern is controlled by changing the focal lengths of the array and principle optical element, the distance between them, and the size of individual lens/reflector in the array. The system is insensitive to component misalignment and has the advantage of achieving high concentration ratio and efficient energy conversion with relatively low cost and compact design.

### CROSS-REFERENCE TO RELATED APPLICATIONS

This application claims the priority and benefit of U.S. Provisional Patent Application No. 61/196,260, entitled “Near-field diffraction superposition of light beams for concentrating solar system”, filed Oct. 15, 2008 by Jun Yang and Xin Zhu, the entire disclosure of which is hereby expressly incorporated by reference.

### BACKGROUND OF THE INVENTION

1. Field of the Disclosure

This disclosure relates generally to concentrating photovoltaic (CPV) solar systems and, more particularly, to the use of optical components to collect or focus sunlight on photovoltaic (PV) solar cells to generate electricity.

2. Brief Description of Related Technology

Conventional CPV systems generally utilize one-level or multi-level optical systems to concentrate incident sunlight onto a much smaller area, where high-efficiency semiconductor PV solar cells are disposed. Current high-efficiency PV cells are fabricated with III-V semiconductor double junction or triple junction heterostructures, which are usually expensive. To reduce the overall system cost, relatively cheaper optical elements such as Fresnel lens and optical reflectors are used to concentrate sunlight, so that high-efficiency solar cells with much smaller size are needed to convert solar energy to electricity. In addition, the concentrated sunlight with higher photon flux increases the energy conversion efficiency.

PV cells fabricated with standard die cleaving or dicing are usually rectangular or square in shape. It is desired that the focused sunlight spot has the same shape and size as the PV cell used with uniform illumination to maximize the energy conversion efficiency.

The technology disclosed in U.S. Patent Application No. US 2008/0041441 [1], used a prism array as concentrator lens, in which individual rectangular prism was designed to deflect the incident sunlight onto a common rectangular target. The combination of multiple prisms enabled uniform illumination across the target area. The limitation of this approach is that the size of each unit prism has to be the same as that of target area. For a PV system with optical concentration ratio of 500, 500 prisms are needed, resulting in high manufacturing cost and assembly difficulty.

Another technology, disclosed in U.S. Patent Application No. 2007/0251568 [2], used a lens/mirror array imaging system. Based on imaging transition and combination, this approach requires the lens/mirror array to be disposed in front of the secondary optical element with a distance of twice the focal length of individual lens/mirror in the array, leading to a bulky system even if a folded reflectance scheme is used. Similarly, individual lens/mirror in the array has to have the same dimension as target area, if equal focal length is used for both the array and secondary optical element as suggested in the disclosure.

The use of lens array to achieve uniform illumination was first reported in laser fusion and laser heating process [3]. The incident laser beam was spatially split by a lens array to form separate beams, which were then recombined at the focus of a principle lens. Due to the coherent property of laser, the lens array has to be disposed adjacently in front of the principle lens in order to alleviate far-field diffraction. In such system, circular lenses are used for uniform circular focus.

Based on the incoherent property of sunlight, this present invention introduces near-field diffraction/transmission superposition in the CPV system to achieve uniform focused illumination, and presents a variety of novel optical concentrating designs.

### SUMMARY OF THE INVENTION

This present invention first utilizes a lens/reflector array to spatially divide the incident sunlight into multiple separate beams. If near-field diffraction/transmission condition is satisfied, these beams exhibit defocused status with different orientation and have similar cross-sectional shape as individual lens/reflectors in the array. A principle optical element is then used to superpose the separate beams into one uniform illumination spot. Assuming all the optical elements have an ideal parabolic surface, these beams would have exactly the same cross-section located at exactly the same position at the focal plane of the principle optical element. Sunlight is polychromic and uniform light and is viewed as incoherent if the sizes of optical elements are far greater than the average sunlight wavelength, which is around 0.5 μm. Therefore, the intensity of each separate beam can be directly added up (superposed) without interference effect, thereby achieving a uniform focused illumination pattern. The pattern is nearly the geometric projection of individual lens/projector in the array, which usually matches the PV solar cells in shape for optimal operation efficiency.

The crucial point of this invention is the use of near-field diffraction/transmission condition. It can be evaluated through the so-called Fresnel number F_{#}. Near-field diffraction/transmission condition is satisfied if Fresnel number F_{#} is greater than one, namely,

$${F}_{\#} = \frac{{d}^{2}}{{L}_{e} λ} > 1 ( more strictly , > 10 ) \qquad ( Eq . 1 )$$

Here d is the dimension of individual lens/reflector in the array, which is typically greater than 1 millimeter. λ, the average wavelength of sunlight, is around 0.5 μm. The effective optical distance, Lₑ, between the array and the focus of the principle optical element can be described by (A/B−1/R)⁻¹, where A and B are ray-matrix elements for a first-order (paraxial) optical system, and R is the wavefront radius of incident light beam with a positive value for converging cases. Under near-field diffraction/transmission condition, the diffraction pattern of individual lens/reflector in the array at the focal plane of the principle optical element is almost its shrunk geometrical projection. Note Fresnel number is greater than 10 for more strict satisfaction of the geometrical projection transmission. The array and principle optical element can be flexibly disposed in CPV system as long as the near-field diffraction/transmission condition is satisfied, which enables high concentration ratio and efficient energy conversion with relatively low cost and compact design.

The size of the focused illumination pattern can be analyzed by geometrical optics. Assume the optical axis is the z-axis, x and y defines the transverse plane. If the array is disposed in front of the principle optical element, we have

$$X = \vert \frac{F}{f} \vert \cdot {d}_{x} \\ and \\ Y = \vert \frac{F}{f} \vert \cdot {d}_{y} ; \qquad ( Eq . 2 )$$

and if the array is disposed behind the principle optical element, we have

$$X = \vert \frac{F - Δ}{f} \vert \cdot {d}_{x} \\ and \\ Y = \vert \frac{F - Δ}{f} \vert \cdot {d}_{y} . \qquad ( Eq . 3 )$$

Here, X and Y is the dimension of the pattern in x- and y-axis, respectively. f is the focal length of individual lens/reflector in the array, F is the focal length of the principal optical element, Δ is the distance between the array and principle optical element. dₓ and d_{y} are the dimensions of each array unit in x- and y-axis, respectively. The size of the illuminated pattern can be adjusted by multiple parameters. The system concentration ratio is defined as the ratio of the overall incident sunlight collection area to the active (illuminated) solar cell area. If the array is disposed in front of the principle optical element, the system concentration ratio is dependent on the ratio of the focal length of the array unit to that of the principle optical element, and the number of array units. It is independent of relative position of the array and principle optical element. If the array is disposed behind the principle optical element, the system concentration ratio is dependent on focal lengths of the array and principle optical element, the distance between them, and the number of array units. In the former design, the system is more simple, tolerant, and reliable. While in the latter design, the system has more freedom to adjust the illuminated area size and thus concentration ratio. Therefore, the present invention provides flexible designs for compact systems with adjustable optical concentration ratio to achieve uniform illumination with desired shape.

The principle optical element can be a single optical element selected from a lens, a reflector, a Fresnel-lens, a Fresnel-reflector and a wave-plate, or it can be a group of these optical elements. The array comprises multiple identical optical elements. Each unit can take the form of a lens, a reflector, a Fresnel-lens and a Fresnel-reflector. For better satisfaction of the near-field diffraction/transmission condition, the array units are preferably defocusing optical elements, such as concave lens, convex mirrors, defocusing Fresnel-lens, and defocusing Fresnel-reflectors. All the optical elements preferably have parabolic surface for ideal operation. In practice, optical elements with near-parabolic aspheric surface can be used to remove the main spherical aberration. For some optical elements with small area or large focal length, spherical surface may be used.

The effective system focus can be located in front of or behind the focus of the principle optical element. In practice, the photovoltaic cell is disposed close to, but not exactly at the focus of the principle optical element. Rather, it is shifted along optical axis in the direction opposite to the effective system focus, in order to avoid far-field diffraction from the edge of the array or the edge of each unit in the array. This offset can be tens to hundreds micrometers, depending on the practical situation.

In one embodiment, the present invention uses a lens/reflector array to spatially divide the incident sunlight into multiple separate beams. Individual units in the array are arranged in such a way that the separate beams undergo near-field diffraction/transmission and superpose with each other to form a uniform illumination pattern with the same shape as individual units in the array.

In another embodiment, the present invention first uses a principle optical element to collect the incident sunlight. A lens/reflector array is then used to spatially divide the collected sunlight into multiple separate beams. These beams undergo near-field diffraction/transmission and superpose with each other to form a uniform illumination pattern with the same shape as individual units in the array.

The present invention provides improved insensitivity to the element misalignment and nonuniform incident light. The effect of misalignment and illumination nonuniformity in an optical system can be simplified by introducing a misaligned effective aperture. The lens/reflector array is insensitive to the X-Y shift in the transverse plane and misalignment of the aperture. The diffraction illumination from the upper part of array is complemented by that from the lower part of array. They superpose on the receiving PV cell and form a uniform and complete illumination spot. Therefore using a lens/reflector array to achieve near-field diffraction/transmission superposition can enhance the insensitivity to X-Y misalignment in photovoltaic concentrator systems and illumination nonuniformity. The present invention can also improve the insensitivity to the displacement of PV solar cell in the optical axis (Z-axis) due to the diffraction/transmission superposition.

The present invention provides the following benefits:
(a) uniform optical concentration with desired shape on the light-receiving solar cell;
(b) tolerant and reliable designs with flexible disposition of optical elements;
(c) adjustable optical concentration ratio with multiple degrees of freedom;
(d) compact system with high optical concentration ratio and low cost manufacturing;
(e) improved insensitivity to sun-tracking X-Y misalignment and illumination nonuniformity;
(f) improved insensitivity to solar cell displacement in optical axis direction.

### BRIEF DESCRIPTION OF THE DRAWING FIGURES

For a more complete understanding of the disclosure, reference should be made to the following detailed description and accompanying drawing figures, in which like reference numerals identify like elements in the figures, and in which:

FIG. 1 is the schematic of a conventional one-level optical design in concentrator photovoltaic (CPV) systems.

FIG. 2 is the schematic of a conventional two-level optical design in CPV systems.

FIG. 3 illustrates the working principle of a one-level optical design using near-field diffraction beam superposition in CPV systems.

FIG. 4 illustrates the working principle of a two-level optical design using near-field diffraction beam superposition in CPV systems, wherein the lens array is disposed behind the front panel as the first-level optical element.

FIG. 5 illustrates the working principle of a two-level optical design using near-field diffraction beam superposition in CPV systems, wherein the lens array is disposed behind the principle optical element as the second-level optical element.

FIG. 6 illustrates the working principle of a two-level optical design using near-field diffraction beam superposition in CPV systems, wherein the reflector array is disposed as the second-level optical element.

FIG. 7 shows that the design in FIG. 5 is insensitive to the X-Y shift and misalignment.

FIG. 8 is the perspective view of a one-level optical design using near-field diffraction beam superposition in a one-dimensional CPV system.

FIG. 9 is the perspective view of a two-level optical design using near-field diffraction beam superposition in a one-dimensional CPV system, wherein the cylindrical lens array is disposed behind the front panel as the first-level optical element.

FIG. 10 is the perspective view of a two-level optical design using near-field diffraction beam superposition in a one-dimensional CPV system, wherein the cylindrical reflector array is disposed as the secondary optical element.

FIG. 11 is the perspective view of a two-level optical design using near-field diffraction beam superposition in a two-dimensional CPV system, wherein the lens array is disposed behind the front panel as the first-level optical element.

FIG. 12 is the perspective view of a two-level optical design using near-field diffraction beam superposition in a two-dimensional CPV system, wherein the reflector array is disposed as the secondary optical element.

While the disclosed methods and configuration are susceptible of embodiments in various forms, there are illustrated in the drawing (and will hereafter be described) specific embodiments of the invention, with the understanding that the disclosure is intended to be illustrative, and is not intended to limit the invention to the specific embodiments described and illustrated herein.

### DETAILED DESCRIPTION OF PREFERRED EMBODIMENTS

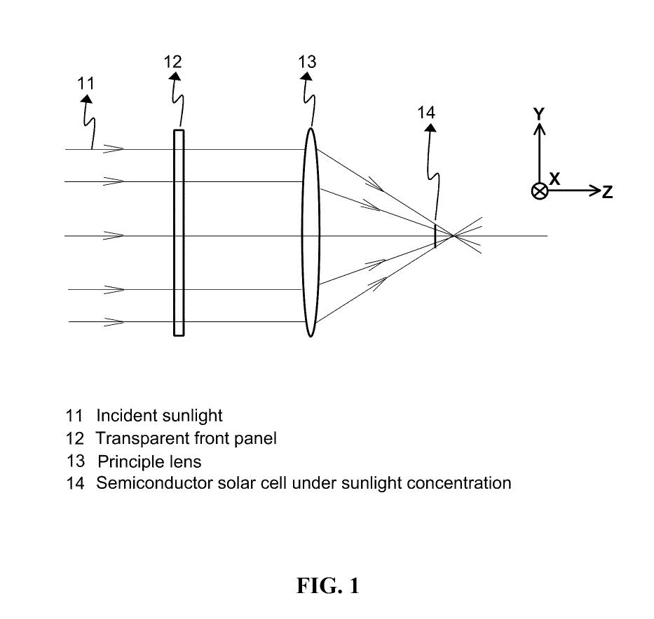

FIG. 1 illustrates the working principle of a conventional one-level optical design in concentrator photovoltaic (CPV) systems. The convex lens is used to concentrate incident sunlight onto a solar cell. In practice, a front panel made of transparent material such as flat glass is used to protect the optical system and solar cells. A concave reflector can also be used to replace the lens with the solar cell disposed accordingly.

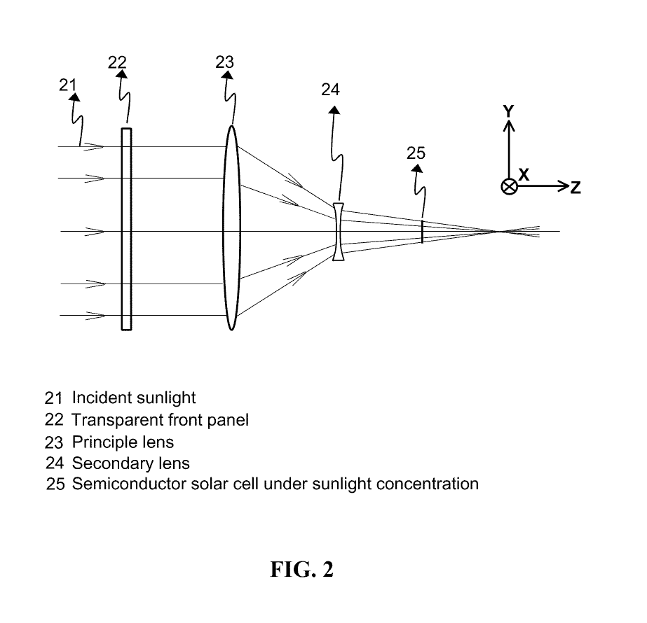

FIG. 2 shows the working principle of a conventional two-level optical design in CPV systems. A convex lens is used as the principle lens to focus the incident sunlight, and a concave lens is used as the secondary lens to illuminate a solar cell. This two-level design allows the use of folded structure to reduce overall system dimension with reflectors.

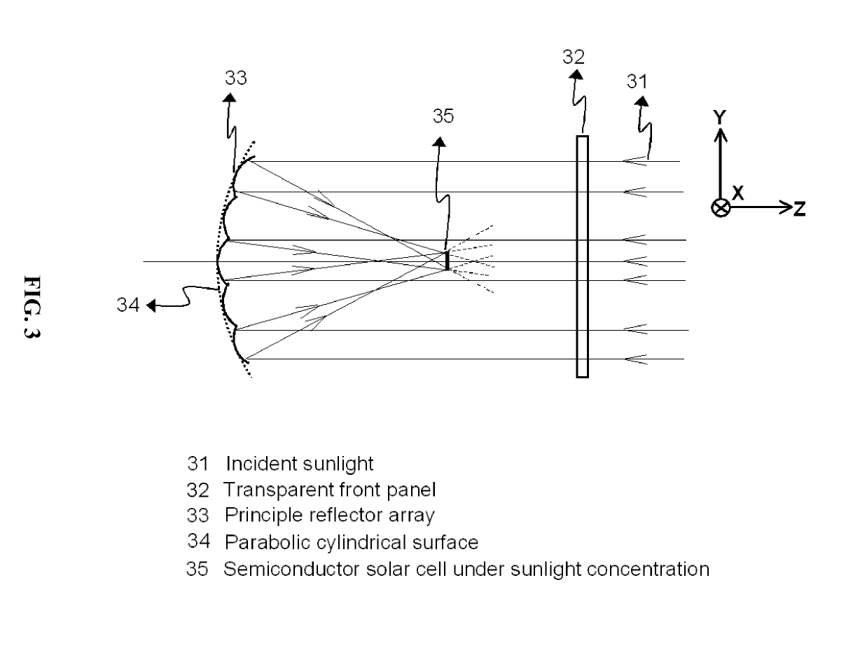

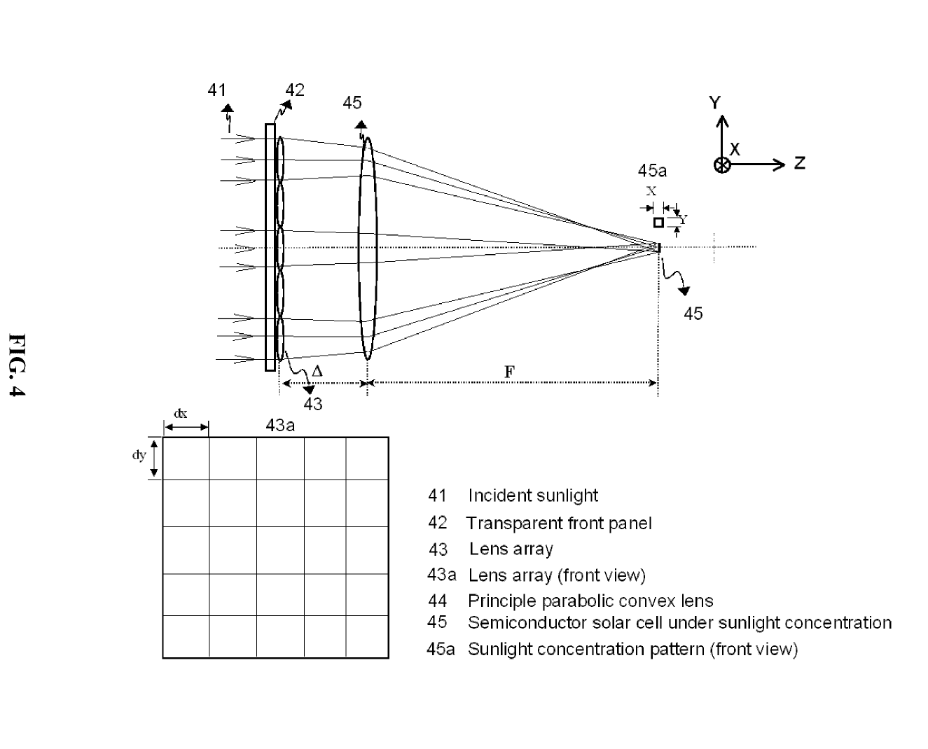

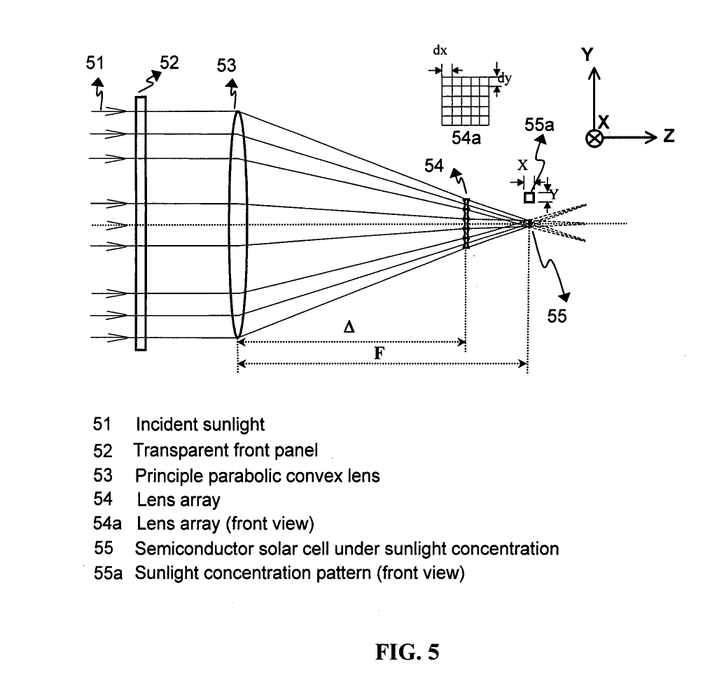

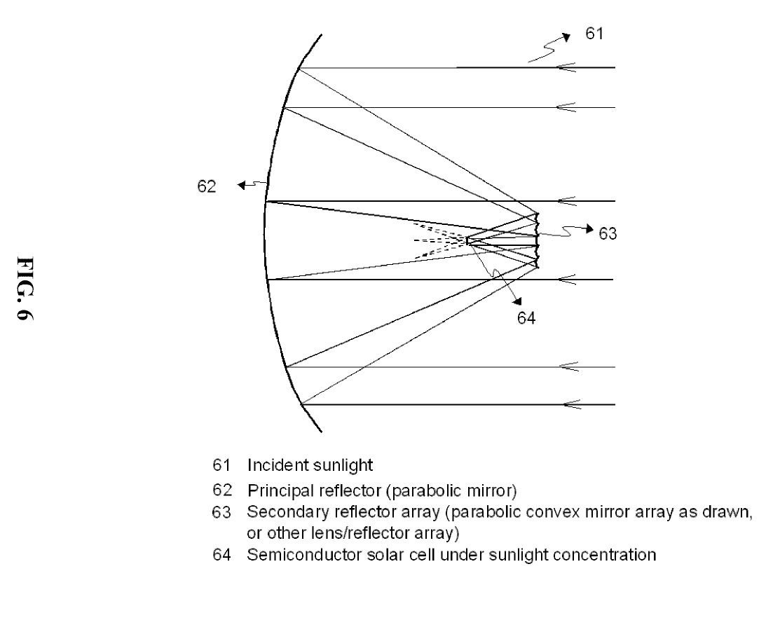

The present invent enables flexible and novel designs to achieve a variety of one-level and two-level CPV systems. The array and principle optical element can be flexibly disposed in the concentrating systems as long as the near-field diffraction/transmission condition is satisfied. They can be focusing or defocusing optical elements and they may be selected from lenses, reflectors, Fresnel-lenses, Fresnel-reflectors and wave-plates. FIG. 3, FIG. 4, FIG. 5 and FIG. 6 illustrate the working principles of some embodiments of the present invention.

FIG. 3 illustrates the working principle of a one-level optical design using near-field diffraction beam superposition in CPV systems. The incident sunlight is divided into five separate beams by an array of five convex reflectors. The reflectors in the array are arranged along a concave plane, so that the five separate beams can automatically superpose and form a uniform illuminated pattern at the focal plane of the array, where a photovoltaic solar cell is disposed. The array assumes the dual responsibilities of incident sunlight splitting and near-field diffraction/transmission superposition.

FIG. 4 illustrates the working principle of a two-level optical design using near-field diffraction beam superposition in CPV systems, wherein a five-by-five array of convex lenses is disposed behind the front panel as the first-level optical element. The individual lens in the array has the dimensions of dₓ and d_{y} in x- and y-axis, respectively. The array spatially splits the incident sunlight into twenty-five separate beams, which undergo near-field diffraction/transmission, and are superposed by a principle convex lens to form a uniform illuminated pattern at the focal plane of the principle lens, where a photovoltaic solar cell is disposed. The solar cell has the dimensions of X and Y in x- and y-axis, respectively, and they are related to dₓ and d_{y} via Eq. 2.

FIG. 5 illustrates the working principle of a two-level optical design using near-field diffraction beam superposition in CPV systems, wherein a five-by-five array of concave lenses is disposed behind a principle convex lens as the second-level optical element. The individual lens in the array has the dimensions of dₓ and d_{y} in x- and y-axis, respectively. The incident light is first focused by the principle convex lens, and then divided into twenty-five separate beams by the array. The separate beams superpose with each other and form a uniform illuminated pattern at the focal plane of the principle lens, where a photovoltaic solar cell is disposed. The solar cell has the dimensions of X and Y in x- and y-axis, respectively, and they are related to dₓ and d_{y} via Eq. 3.

FIG. 6 illustrates the working principle of a two-level optical design using near-field diffraction beam superposition in CPV systems, wherein an array of five convex reflectors is disposed as the second-level optical element. It uses a folded design to reduce the overall system dimension. The incident light is first reflected and focused by a principle concave reflector, and divided into five separate beams by the array. These separate beams superpose with each other and form a uniform illuminated pattern at the focal plane of the principle reflector, where a photovoltaic solar cell is disposed.

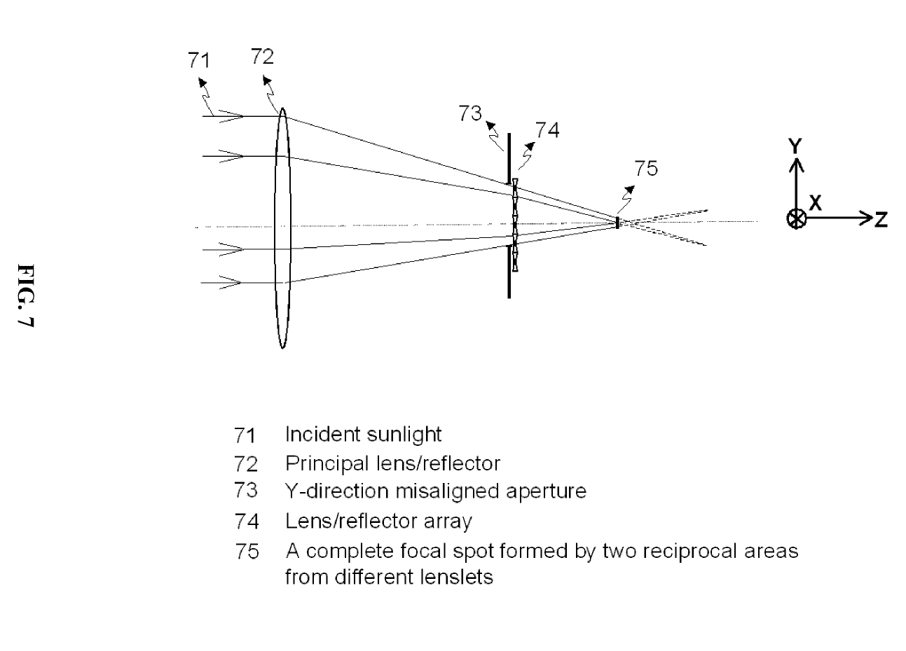

FIG. 7 shows that the design in FIG. 5 is insensitive to the X-Y shift and misalignment. In case of shift or misalignment in Y-direction as indicated by the misaligned effective aperture, the diffraction illumination from the upper part of array is complemented by that from the lower part of array. They superpose on the receiving solar cell and form a uniform and complete illumination spot. The result is the same notwithstanding the misalignment. Accordingly, in case of shift or misalignment in X-direction, the diffraction illumination from the left part of array is complemented by that from the right part of array. Other designs of the present invention also have this benefit.

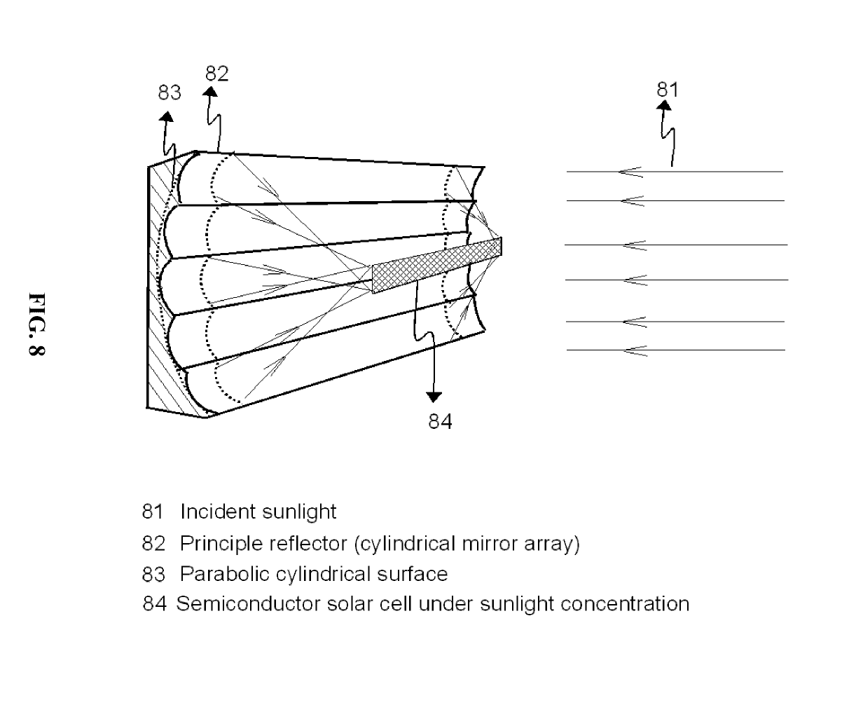

In practice, concentrating solar systems may be one-dimensional or two-dimensional. For one-dimensional application, cylindrical symmetry is used, and one-dimensional parabolic/aspheric cylindrical optical elements are generally employed. FIG. 8 is the perspective view of a one-level optical design using near-field diffraction beam superposition in a one-dimensional CPV system. Its working principle is explained in FIG. 3. The cylindrical reflector array is a one-dimensional array and light concentration only occurs in one dimension.

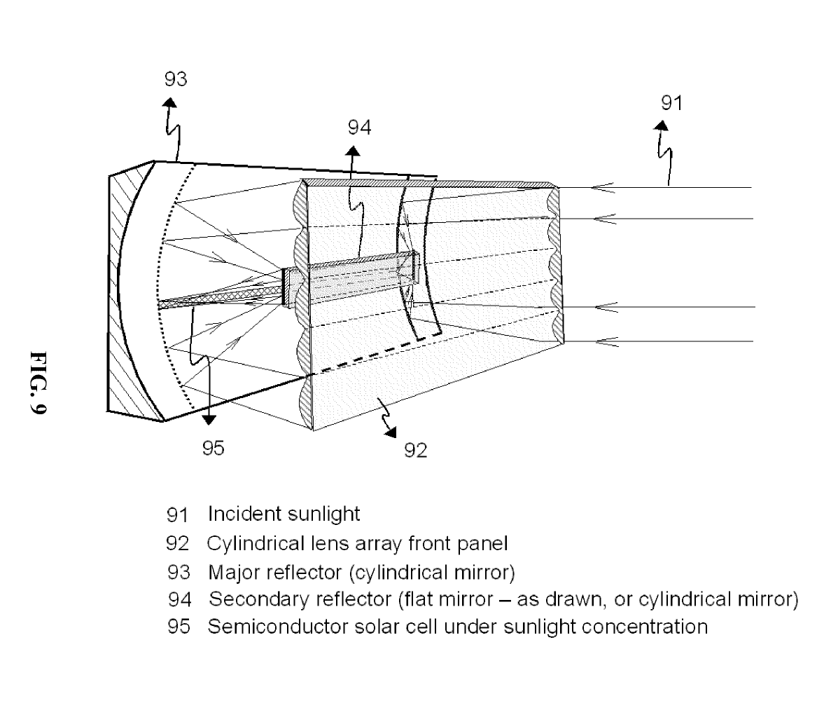

FIG. 9 is the perspective view of a two-level optical design using near-field diffraction beam superposition in a one-dimensional CPV system, wherein the cylindrical convex lens array is disposed behind the front panel as the first-level optical element. The incident sunlight is divided into five separate beams by the array. The principle optical element here comprises a primary concave reflector and a secondary reflector. The five separate beams are superposed after double reflection and form a uniform illuminated pattern on a solar cell. Light concentration only occurs in one direction. The use of double reflection can further reduce the system dimension.

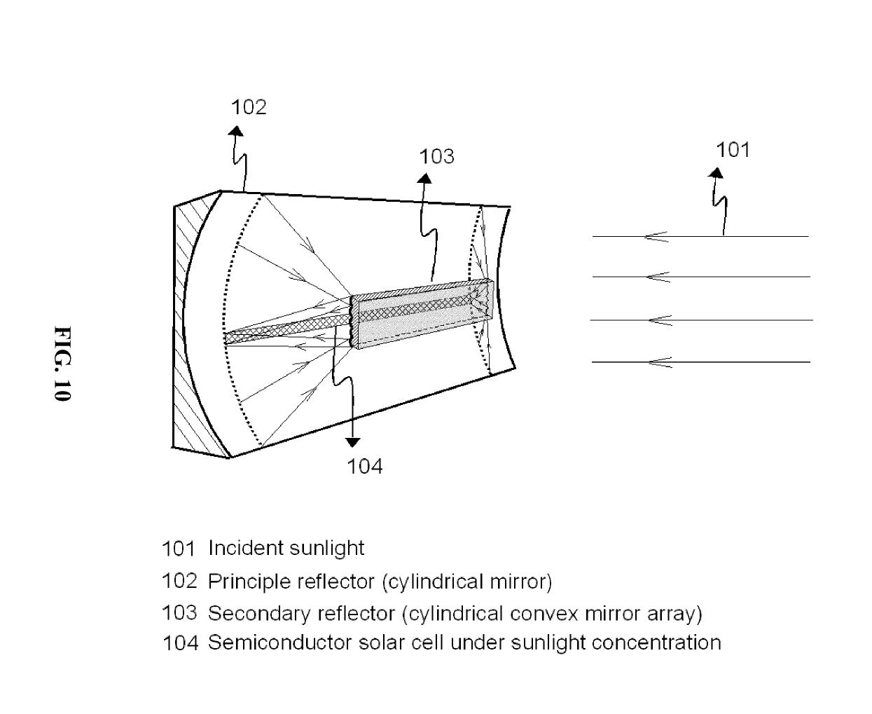

FIG. 10 is the perspective view of a two-level optical design using near-field diffraction beam superposition in a one-dimensional CPV system, wherein the cylindrical convex reflector array is disposed as the secondary optical element. Its working principle is explained in FIG. 6. Light concentration only occurs in one direction.

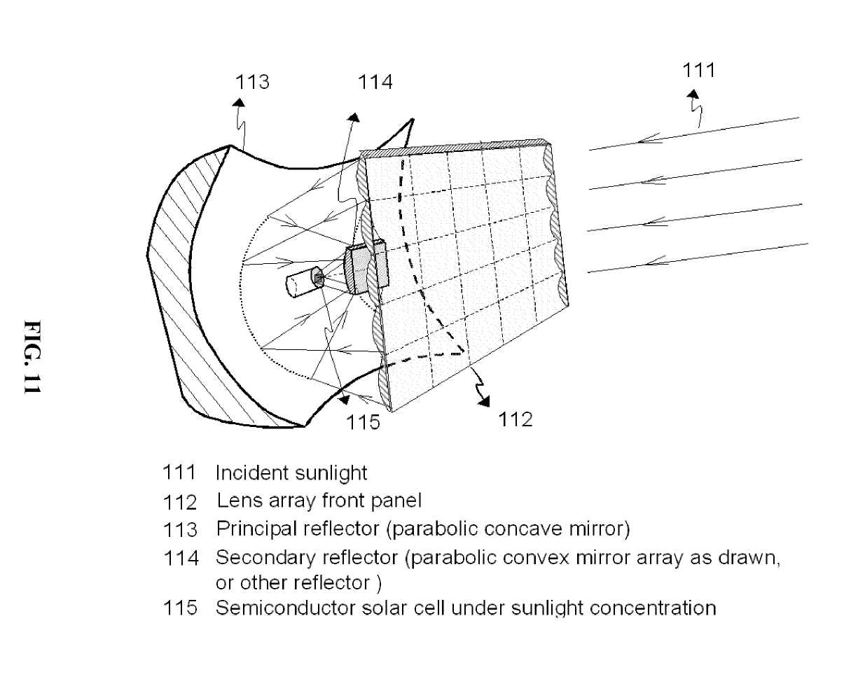

For two-dimensional concentrating application, two-dimensional parabolic or aspheric optical elements are generally employed. FIG. 11 is the perspective view of a two-level optical design using near-field diffraction beam superposition in a two-dimensional CPV system, wherein a five-by-five array of convex lenses is disposed behind the front panel as the first-level optical element. Its working principle is the same as in FIG. 9. The lens array divides the incident sunlight into twenty-five separate beams, which superpose after double reflection and form a uniform illuminated pattern on a solar cell. Light concentration occurs in two directions and the size of the solar cell is reduced.

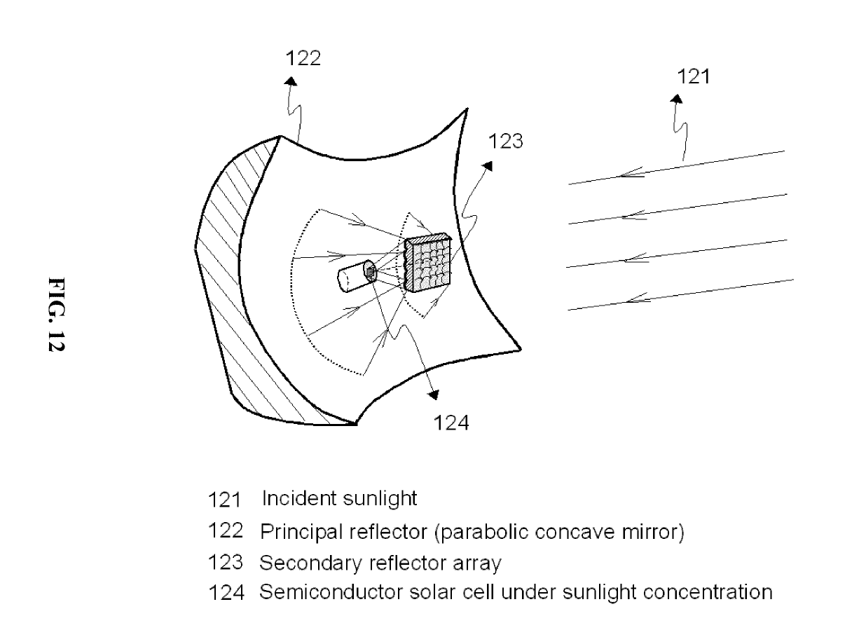

FIG. 12 is the perspective view of two-level optical design using near-field diffraction beam superposition in a two-dimensional CPV system, wherein a five-by-five array of convex reflectors is disposed as the secondary optical element. Its working principle is explained in FIG. 6. Light concentration occurs in two directions.

Table 1 lists possible configurations of one-level concentration for both one-dimensional and two-dimensional CPV systems. Table 2 lists possible configurations of two-level concentration for both one-dimensional and two-dimensional CPV systems. For simplicity, lens and Fresnel-lens are both called lens; reflector and Fresnel-reflector are both called reflector in the tables.

TABLE 1
Proposed configurations of one-level
optical near-field beam superposition

| | 1-D concentration | 2-D concentration |
|---|---|---|
| Front panel | Flat glass | Flat glass |
| Principle | Cylindrical | Lens/reflector array |
| lens/reflector | lens/reflector array | |

TABLE 2
Proposed configurations of two-level optical near-field beam superposition

| | 1-D concentration | | 2-D concentration | |
|---|---|---|---|---|
| Front panel | Flat glass | Flat glass | Flat glass | Flat glass |
| First-level | Cylindrical | Cylindrical | Lens/reflector array | Lens/reflector |
| lens/reflector | lens/reflector array | lens/reflector | | |
| Second-level | Cylindrical | Cylindrical | Lens/reflector | Lens/reflector array |
| lens/reflector | lens/reflector | lens/reflector array | | |

What is claimed is:

1. A concentrating photovoltaic system comprised of:
a lens/reflector array that first spatially divide the incident sunlight into multiple separate incoherent beams;
a principle optical element that superpose the multiple separate beams that undergo near-field diffraction/transmission, into a uniform illumination pattern with the same shape as individual units in the array; and
a photovoltaic cell disposed close to the focus of the principle optical element where the said uniform illumination pattern is formed.

2. The concentrating photovoltaic system of claim 1, wherein the array and principle optical element are flexibly disposed as long as the near-field diffraction/transmission condition is satisfied, in which case the separate sunlight beams divided by the array are nearly the geometric projections of individual units in the array.

3. The concentrating photovoltaic system of claim 1,
wherein individual unit in the array has a transverse size of d,
wherein the effective optical distance between the array and the focus of the principle optical element is Lₑ,
wherein the near-field diffraction/transmission condition is defined as Fresnel number, F_{#}=d²/Lₑλ>1 (more strictly, >10), where λ is the average wavelength of sunlight.

4. The concentrating photovoltaic system of claim 1,
wherein the array comprises multiple identical optical elements, each unit selected from a lens, a reflector, a Fresnel-lens and a Fresnel-reflector,
wherein the optical elements in the array have parabolic or desired aspheric surface to remove the main spherical aberration,
wherein the optical elements in the array have cylindrical symmetry in one dimensional applications.

5. The concentrating photovoltaic system of claim 1, wherein individual unit in the array has the same shape as the photovoltaic cell, which is usually rectangular or square.

6. The concentrating photovoltaic system of claim 1,
wherein the principle optical element comprises a single optical element selected from a lens, a reflector, a Fresnel-lens, a Fresnel-reflector and a wave plate, or a group of such optical elements,
wherein the principle optical element has parabolic or desired aspheric surface to remove the main spherical aberration,
wherein the principle optical element has cylindrical symmetry in one dimensional applications.

7. A concentrating photovoltaic system comprised of:
a principle optical element that first collects the incident sunlight;
a lens/reflector array that spatially divide the collected sunlight into multiple separate incoherent beams, which undergo near-field diffraction/transmission, and superpose with each other to form a uniform illumination pattern with the same shape as the individual unit in the array; and
a photovoltaic cell disposed close to the focus of the principle optical element where the said uniform illumination pattern is formed.

8. The concentrating photovoltaic system of claim 7, wherein the array and principle optical element are flexibly disposed as long as the near-field diffraction/transmission condition is satisfied, in which case the separate sunlight beams divided by the array are nearly the geometric projections of individual units in the array.

9. The concentrating photovoltaic system of claim 7, wherein individual unit in the array has a transverse size of d, wherein the effective optical distance between the array and the focus of the principle optical element is Lₑ,
wherein the near-field diffraction/transmission condition is defined as Fresnel number, F_{#}=d²/Lₑλ>1 (more strictly, >10), where λ is the average wavelength of sunlight.

10. The concentrating photovoltaic system of claim 7,
wherein the principle optical element comprises a single optical element selected from a lens, a reflector, a Fresnel-lens, a Fresnel-reflector and a wave plate, or a group of such optical elements,
wherein the principle optical element has parabolic or desired aspheric surface to remove the main spherical aberration,
wherein the principle optical element has cylindrical symmetry in one dimensional applications.

11. The concentrating photovoltaic system of claim 7,
wherein the array comprises multiple identical optical elements, each unit selected from a lens, a reflector, a Fresnel-lens and a Fresnel-reflector,
wherein the optical elements in the array have parabolic or desired aspheric surface to remove the main spherical aberration,
wherein the optical elements in the array have cylindrical symmetry in one dimensional applications.

12. The concentrating photovoltaic system of claim 7, wherein the individual unit in the array has the same shape as the photovoltaic cell, which is usually rectangular or square.

13. A concentrating photovoltaic system comprised of:
a lens/reflector array, disposed on a curved surface, that spatially divide the incident sunlight into multiple separate incoherent beams, which undergo near-field diffraction/transmission, and superpose with each other to form a uniform illumination pattern with the same shape as individual unit in the array; and
a photovoltaic cell disposed close to the effective focus of the array where the said uniform illumination pattern is formed.

14. The concentrating photovoltaic system of claim 13,
wherein individual unit in the array has a transverse size of d,
wherein the effective focal length of the array is Lₑ,
wherein the near-field diffraction/transmission condition is defined as Fresnel number, F_{#}=d²/Lₑλ>1 (more strictly, >10), where λ, is the average wavelength of sunlight.

15. The concentrating photovoltaic system of claim 13,
wherein the array comprises multiple identical optical elements, each unit selected from a lens, a reflector, a Fresnel-lens and a Fresnel-reflector,
wherein the optical elements in the array have parabolic or desired aspheric surface to remove the main spherical aberration,
wherein the optical elements in the array have cylindrical symmetry in one dimensional applications.

16. The concentrating photovoltaic system of claim 13, wherein individual unit in the array has the same shape as the photovoltaic cell, which is usually rectangular or square.
